(19) United States
(12) Patent Application Publication
(10) Pub. No.: US 2025/0345821 A1
(43) Pub. Date: Nov. 13, 2025

(54) DEPOSITION MASK

(71) Applicant: Samsung Display Co., LTD., Yongin-si (KR)

(72) Inventors: Jeong Kuk KIM, Yongin-si (KR); Duck Jung LEE, Yongin-si (KR); Ji Hyun JUNG, Yongin-si (KR)

(21) Appl. No.: 19/013,348

(22) Filed: Jan. 8, 2025

(30) Foreign Application Priority Data
May 13, 2024 (KR) 10-2024-0062563

(51) Int. Cl. B05C 21/00

(52) U.S. Cl. CPC B05C 21/005

(57) ABSTRACT

A deposition mask includes a mask substrate including a cell area and a cell peripheral area; a mask membrane positioned in the cell area of the mask substrate, where a pixel opening is defined through the mask membrane, and the mask membrane includes a mask shadow surrounding the pixel opening; and a mask frame positioned on the cell peripheral area of the mask substrate, where the mask frame includes the mask substrate, a mask inorganic layer and a mask metal layer. The mask metal layer does not overlap the cell area in a direction perpendicular to the mask substrate and is in contact with the mask substrate, and the mask metal layer includes a portion condensed or melted by laser irradiation.

This application claims priority to Korean Patent Application No. 10-2024-0062563, filed on May 13, 2024, and all the benefits accruing therefrom under 35 U.S.C. § 119, the content of which in its entirety is herein incorporated by reference.

### BACKGROUND

### (1) Field

Embodiments of the disclosure relates to a deposition mask.

### (2) Description of the Related Art

A wearable device has been developed in the form of glasses or a helmet so that a focus is formed at a distance close to a user's eyes. For example, the wearable device may be a head mounted display (HMD) device or an AR glasses. The wearable device provides a user with an augmented reality (AR) screen or a virtual reality (VR) screen.

The wearable device such as the HMD device or the AR glasses is typically desired to have a display specification of a minimum 2000 pixels per inch (PPI) to allow a user to use it for a long time without dizziness. To this end, an organic light emitting diode on silicon (OLEDoS) technology, which is related to a high-resolution compact organic light emitting display device, has emerged. The OLEDoS technology is the technology for arranging an organic light emitting diode (OLED) on a semiconductor wafer substrate on which a complementary metal oxide semiconductor (CMOS) is disposed.

### BRIEF SUMMARY

Embodiments of the disclosure provide a silicon deposition mask that may manufacture a display panel of high resolution.

Embodiments of the disclosure provide a deposition mask in which a tight adhesion to a display panel is improved.

In an embodiment of the disclosure, a deposition mask includes a mask substrate including a cell area and a cell peripheral area; a mask membrane positioned in the cell area of the mask substrate, where a pixel opening is defined through the mask membrane, and the mask membrane includes a mask shadow surrounding the pixel opening; and a mask frame positioned on the cell peripheral area of the mask substrate, where the mask frame includes the mask substrate, a mask inorganic layer and a mask metal layer. In such an embodiment, the mask metal layer does not overlap the cell area in a direction perpendicular to the mask substrate and is in contact with the mask substrate, and the mask metal layer includes a portion condensed or melted by laser irradiation.

In an embodiment, the mask metal layer may include a first surface positioned in a direction opposite to a direction in which the mask substrate may be positioned, and the first surface includes a heat-affected portion defined by the portion condensed or melted by laser irradiation.

In an embodiment, the heat-affected portion may have a smoked shape, a corrugated shape or an embossed shape.

In an embodiment, the first surface may be entirely covered by the heat-affected portion.

In an embodiment, the heat-affected portion may include a protrusion more protruded in the direction perpendicular to the mask substrate than the first surface.

In an embodiment, the heat-affected portion may include a recess more recessed in the direction perpendicular to the mask substrate than the first surface.

In an embodiment, the mask substrate may further include an upper surface directed toward the mask inorganic layer and a lower surface opposite the upper surface, the mask inorganic layer is in contact with the upper surface of the mask substrate, and the upper surface of the mask substrate may include an exposed portion which is not in contact with the mask inorganic layer.

In an embodiment, the mask metal layer may overlap the exposed portion of the upper surface in the direction perpendicular to the mask substrate.

In an embodiment, the mask metal layer may be in contact with the lower surface of the mask substrate.

In an embodiment, the mask metal layer may be in contact with the upper surface of the mask substrate.

In an embodiment, the mask metal layer may be spaced apart from the mask inorganic layer in a direction parallel with the mask substrate, and the mask metal layer may be positioned on a same plane parallel with the mask substrate as the mask.

In an embodiment, the mask metal layer may have a height of about 500 nanometers or greater.

In an embodiment, the mask inorganic layer may include a tip more protruded toward a center of the cell area than a side of the mask substrate, and the mask metal layer may do not overlap the protruded tip of the mask inorganic layer in the direction perpendicular to the mask substrate.

In an embodiment, the mask substrate may include silicon, and the mask substrate may have a circular shape.

In an embodiment, the mask frame may define a mask opening on a plane, and the mask metal layer surrounds the mask opening on the plane.

In an embodiment, the mask metal layer may expose the mask opening and may be formed in a mesh shape on a plane.

In an embodiment, the mask inorganic layer may include an inorganic insulating material, and the mask inorganic layer and the mask shadow may include a same material as each other.

In an embodiment of the disclosure, a deposition mask includes a mask substrate including a cell area, an edge area and a cell peripheral area positioned between the cell area and the edge area; a mask membrane positioned in the cell area of the mask substrate; a mask inorganic layer positioned on the cell peripheral area of the mask substrate; and a mask metal layer positioned on the cell peripheral area and the edge area of the mask substrate, where the mask metal layer includes metal. In such an embodiment, the mask metal layer includes a heat-affected portion.

In an embodiment, the cell peripheral area may include a first cell peripheral area which overlaps the mask metal layer in a direction perpendicular to the mask substrate, and a second cell peripheral area which does not overlap the mask metal layer in the direction perpendicular to the mask substrate, and the mask metal layer does not overlap the cell area in the direction perpendicular to the mask substrate.

In an embodiment, the mask metal layer may include a first surface positioned in a direction opposite to a direction in which the mask substrate is positioned, and the first surface includes the heat-affected portion.

In an embodiment, an electronic device comprising: a display device including a display panel formed using a deposition mask; the mask substrate including a cell area and a cell peripheral area; a mask membrane positioned in the cell area of the mask substrate, wherein a pixel opening is defined through the mask membrane, and the mask membrane includes a mask shadow surrounding the pixel opening; and a mask frame positioned on the cell peripheral area of the mask substrate, wherein the mask frame includes the mask substrate, a mask inorganic layer and a mask metal layer, wherein the mask metal layer does not overlap the cell area in a direction perpendicular to the mask substrate and is in contact with the mask substrate, and the mask metal layer includes a portion condensed or melted by laser irradiation.

In the deposition mask according to embodiments, a mask shadow may be formed at a portion that overlaps a cell area of a mask substrate, such that a deposition mask that manufactures a display panel of high resolution may be provided.

The deposition mask according to embodiments may include a metal layer radiated with a laser on a mask substrate, thereby improving a tight adhesion to a display panel.

The effects according to the embodiments of the disclosure are not limited to those mentioned above and more various effects are included in the following description of the disclosure.

### BRIEF DESCRIPTION OF THE DRAWINGS

The above and other features of embodiments of the disclosure will become more apparent by describing in further detail embodiments thereof with reference to the attached drawings, in which:

FIG. 1 is a perspective view illustrating a head mounted electronic device according to an embodiment;

FIG. 2 is an exploded perspective view illustrating an example of the head mounted electronic device of FIG. 1;

FIG. 3 is a perspective view illustrating a head mounted electronic device according to an embodiment;

FIG. 4 is an exploded perspective view illustrating a display device according to an embodiment;

FIG. 5 is a cross-sectional view illustrating an example in which a portion of a display panel according to an embodiment is cut;

FIG. 6 is a schematic plan view of a mask according to an embodiment;

FIG. 7 is an enlarged plan view of an area A in FIG. 6;

FIG. 8 is a cross-sectional view taken along line X1-X1′ in FIG. 7;

FIG. 9 is an enlarged cross-sectional view of an area T in FIG. 8;

FIG. 10 is an enlarged cross-sectional view of an area T in FIG. 8, according to another embodiment;

FIG. 11 is an enlarged cross-sectional view of an area T in FIG. 8, according to another embodiment;

FIG. 12 is an enlarged cross-sectional view of an area T in FIG. 8, according to another embodiment;

FIG. 13 is a cross-sectional view taken along line X1-X1′ in FIG. 7, according to another embodiment;

FIG. 14 is a schematic plan view of a mask according to another embodiment;

FIG. 15 is a cross-sectional view taken along line X3-X3′ in FIG. 14; and

FIG. 16 is a cross-sectional view taken along line X3-X3′ in FIG. 14, according to another embodiment.

FIG. 17 is a block diagram of an electronic device according to one embodiment of the present disclosure.

FIG. 18 is a schematic diagram of an electronic device according to various embodiments of the present disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

Hereinafter, embodiments of the disclosure will be described in detail with reference to the accompanying drawings.

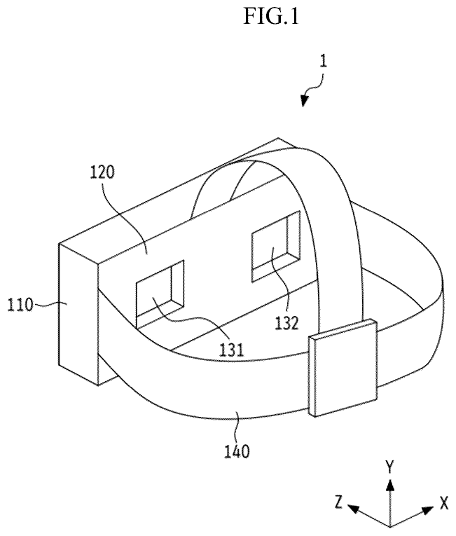

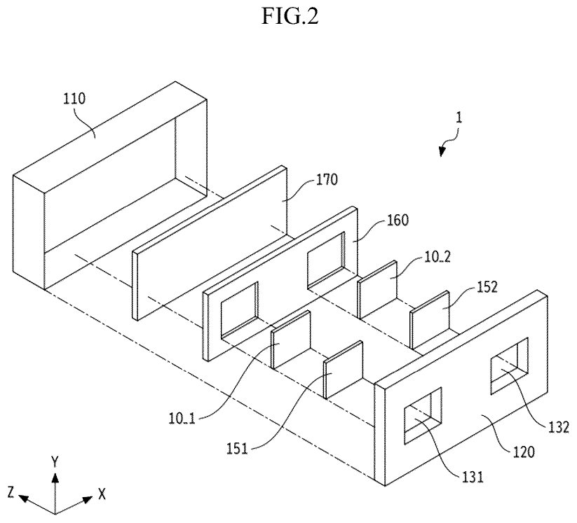

FIG. 1 is a perspective view illustrating a head mounted electronic device according to an embodiment. FIG. 2 is an exploded perspective view illustrating an example of the head mounted electronic device of FIG. 1;

Referring to FIGS. 1 and 2, a head mounted electronic device 1 according to an embodiment includes a display device accommodating portion 110, an accommodating portion cover 120, a first eyepiece 131, a second eyepiece 132, a head mounted band 140, a first display device 10_1, a second display device 10_2, a middle frame 160, a first optical member 151, a second optical member 152, a control circuit board 170 and a connector.

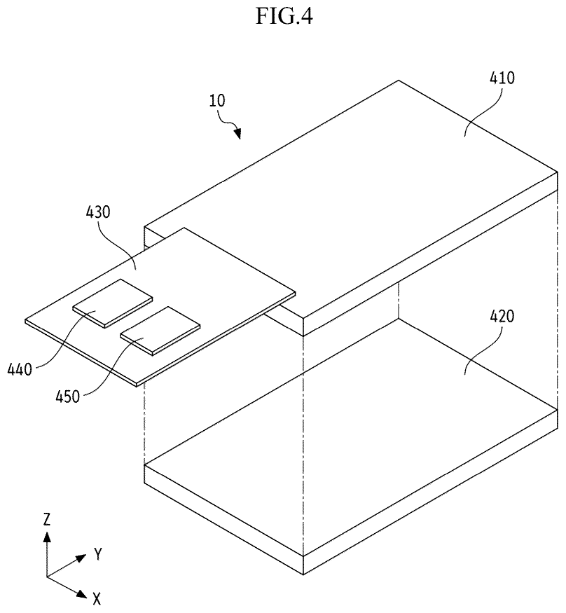

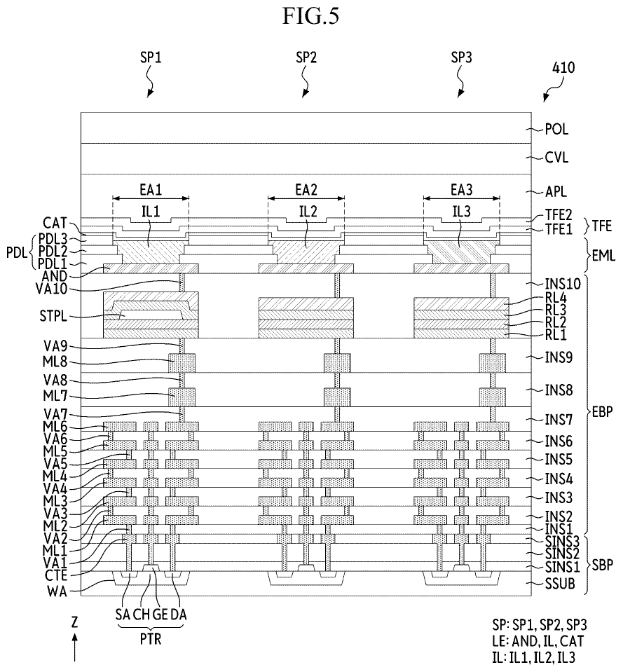

The first display device 10_1 provides an image to a user's left eye, and the second display device 10_2 provides an image to the user's right eye. Each of the first display device 10_1 and the second display device 10_2 is substantially the same as a display device 10 that will be described with reference to FIGS. 4 and 5. Therefore, the features of the first display device 10_1 and the second display device 10_2 will be described later in greater detail with reference to the display device 10 shown in FIGS. 4 and 5.

The first optical member 151 may be disposed between the first display device 10_1 and the first eyepiece 131. The second optical member 152 may be disposed between the second display device 10_2 and the second eyepiece 132. Each of the first optical member 151 and the second optical member 152 may include at least one convex lens.

The middle frame 160 may be disposed between the first display device 10_1 and the control circuit board 170, and may be disposed between the second display device 10_2 and the control circuit board 170. The middle frame 160 serves to support and fix the first display device 10_1, the second display device 10_2 and the control circuit board 170.

The control circuit board 170 may be disposed between the middle frame 160 and the display device accommodating portion 110. The control circuit board 170 may be connected to the first display device 10_1 and the second display device 10_2 through the connector. The control circuit board 170 may convert an image source input from the outside into digital video data, and may transmit the digital video data to the first display device 10_1 and the second display device 10_2 through the connector.

The control circuit board 170 may transmit the digital video data corresponding to a left-eye image optimized for the user's left eye to the first display device 10_1, and may transmit the digital video data corresponding to a right-eye image optimized for the user's right eye to the second display device 10_2. Alternatively, the control circuit board 170 may transmit the same digital video data to the first display device 10_1 and the second display device 10_2.

The display device accommodating portion 110 serves to accommodate the first display device 10_1, the second display device 10_2, the middle frame 160, the first optical member 151, the second optical member 152, the control circuit board 170 and the connector. The accommodating portion cover 120 is disposed to cover one open surface of the display device accommodating portion 110. The accommodating portion cover 120 may include a first eyepiece 131 in which the user's left eye is disposed and a second eyepiece 132 in which the user's right eye is disposed. Although FIGS. 1 and 2 illustrate an embodiment where the first eyepiece 131 and the second eyepiece 132 are disposed separately, the embodiment of the disclosure is not limited thereto. In another embodiment, the first eyepiece 131 and the second eyepiece 132 may be combined into one.

The first eyepiece 131 may be aligned with the first display device 10_1 and the first optical member 151, and the second eyepiece 132 may be aligned with the second display device 10_2 and the second optical member 152. Therefore, the user may view the image of the first display device 10_1, which is enlarged in a virtual image by the first optical member 151, through the first eyepiece 131, and may view the image of the second display device 10_2, which is enlarged in a virtual image by the second optical member 152, through the second eyepiece 132.

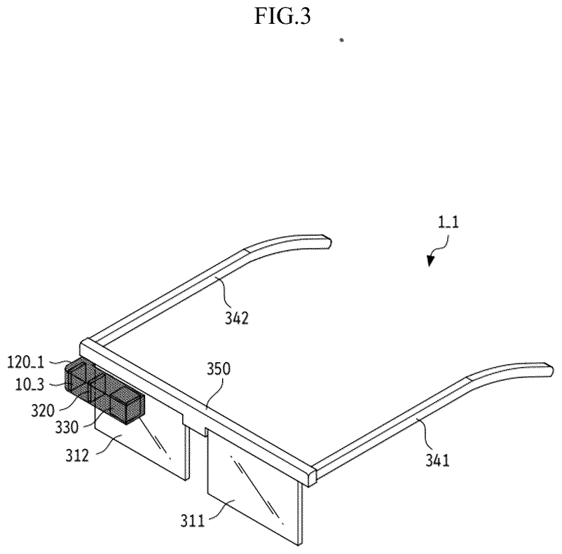

The head mounted band 140 serves to fix the display device accommodating portion 110 to the user's head so that the first eyepiece 131 and the second eyepiece 132 of the accommodating portion cover 120 are disposed on the user's left and right eyes, respectively. In an embodiment where the display device accommodating portion 110 is desired to be implemented to be lightweight and small, the head mounted electronic device 1 may include a glasses frame as shown in FIG. 3 instead of the head mounted band 140.

In an embodiment, the head mounted electronic device 1 may further include a battery for supplying a power source, an external memory slot capable of accommodating an external memory, an external connection port for receiving an image source, and a wireless communication module. The external connection port may be a universal serial bus (USB) terminal, a display port or a high-definition multimedia interface (HDMI) terminal, and the wireless communication module may be a 5G communication module, a 4G communication module, a Wi-Fi module or a Bluetooth module.

FIG. 3 is a perspective view illustrating a head mounted electronic device according to an embodiment.

Referring to FIG. 3, a head mounted electronic device 1_1 according to an embodiment may be a glasses-type display device in which a display device accommodating portion 120_1 is implemented to be lightweight and small. The head mounted electronic device 1_1 according to an embodiment may include a display device 10_3, a left-eye lens 311, a right-eye lens 312, a support frame 350, glasses frame legs 341 and 342, an optical member 320, an optical path conversion member 330, and a display device accommodating portion 120_1.

The display device 10_3 shown in FIG. 3 is substantially the same as the display device 10 described with reference to FIGS. 4 and 5. Therefore, the features of the first display device 10_1 and the second display device 10_2 will be described in greater detail with reference to the display device 10 shown in FIGS. 4 and 5.

The display device accommodating portion 120_1 may include a display device 10_3, an optical member 320, and an optical path conversion member 330. An image displayed on the display device 10_3 may be enlarged by the optical member 320, and an optical path may be converted by the optical path conversion member 330 such that the image may be provided to the user's right eye through the right-eye lens 312. Accordingly, the user may view an augmented reality image in which a virtual image displayed on the display device 10_3 and a real image viewed through the right-eye lens 312 are combined through the right eye.

Although FIG. 3 illustrates an embodiment where the display device accommodating portion 120_1 is disposed at the right end of the support frame 350, the embodiment of the disclosure is not limited thereto. In another embodiment, for example, the display device accommodating portion 120_1 may be disposed at the left end of the support frame 350, and in such an embodiment, the image of the display device 10_3 may be provided to the user's left eye. Alternatively, the display device accommodating portion 120_1 may be disposed at both the left end and the right end of the support frame 350, and in such an embodiment, the user may view the image displayed on the display device 10_3 through both the left eye and the right eye.

FIG. 4 is an exploded perspective view illustrating a display device according to an embodiment.

Referring to FIG. 4, the display device 10 according to an embodiment is a device for displaying a moving image or a still image. The display device 10 according to an embodiment may be applied to a portable electronic device such as a mobile phone, a smart phone, a tablet personal computer (PC), a mobile communication terminal, an electronic diary, an electronic book, a portable multimedia player (PMP), a navigator and an ultra mobile PC (UMPC). For example, the display device 10 may be applied to a television, a laptop computer, a monitor, a signboard or a display unit of Internet of things (IoT). Also, the display device 10 may be applied to a smart watch, a watch phone, and a head mounted display (HMD) for implementing virtual reality and augmented reality.

The display device 10 according to an embodiment includes a display panel 410, a heat dissipation layer 420, a circuit board 430, a driving circuit 440 and a power supply circuit 450.

The display panel 410 may be formed in a planar shape similar to a rectangular shape. In an embodiment, for example, the display panel 410 may have a planar shape similar to a rectangular shape having short sides in a first direction (X-axis direction) and long sides in a second direction (Y-axis direction) crossing the first direction (X-axis direction). A corner where the short side in the first direction (X-axis direction) and the long side in the second direction (Y-axis direction) meet in the display panel 410 may be rounded to have a predetermined curvature or formed at a right angle. Here, a third direction (Z-axis direction) may be a direction perpendicular to the first and second direction or a thickness direction of the display panel 410. The planar shape (or a shape viewed in the third direction) of the display panel 410 may be formed to be similar to other polygonal shape, a circular shape or an oval shape without being limited to the rectangular shape. A planar shape of the display device 10 may follow the planar shape of the display panel 410, but the embodiment of the disclosure is not limited thereto.

The display panel 410 includes a display area for displaying an image and a non-display area for not displaying an image.

The display area includes a plurality of pixels, and each of the pixels includes a plurality of subpixels (SP1, SP2 and SP3 of FIG. 5). The plurality of subpixels SP1, SP2 and SP3 include a plurality of pixel transistors. The plurality of pixel transistors may be formed through a semiconductor process, and may be disposed on a semiconductor substrate (SSUB of FIG. 5). In an embodiment, for example, the plurality of pixel transistors may include or be formed of complementary metal oxide semiconductors (CMOS).

The heat dissipation layer 420 may overlap the display panel 410 in the third direction (Z-axis direction), that is, the thickness direction of the display panel 410. The heat dissipation layer 420 may be disposed on one surface of the display panel 410, for example, a rear surface. The heat dissipation layer 420 serves to emit heat generated from the display panel 410. The heat dissipation layer 420 may include a metal layer such as graphite, silver (Ag), copper (Cu) or aluminum (Al), which has high thermal conductivity.

The circuit board 430 may be electrically connected to a plurality of pads of a pad area PDA of the display panel 410 by using a conductive adhesive member such as an anisotropic conductive film. The circuit board 430 may be a flexible printed circuit board or a flexible film, which has a flexible material. Although FIG. 4 illustrates an embodiment of the display device 10 in a state where the circuit board 430 is unfolded, the circuit board 430 may be bent. When the circuit board 430 is bent, one end of the circuit board 430 may be disposed on the rear surface of the display panel 410. One end of the circuit board 430 may be opposite to the other end of the circuit board 430 connected to the plurality of pads of the pad area PDA of the display panel 410 by using a conductive adhesive member.

The driving circuit 440 may receive digital video data and timing signals from the outside. The driving circuit 440 may generate a scan timing control signal, an emission timing control signal and a data timing control signal for controlling the display panel 410, in accordance with the timing signals.

The power supply circuit 450 may generate a plurality of panel driving voltages in accordance with a power voltage from the outside.

Each of the driving circuit 440 and the power supply circuit 450 may be formed of an integrated circuit (IC) and attached to one surface of the circuit board 430.

FIG. 5 is a cross-sectional view illustrating an example in which a portion of a display panel according to an embodiment is cut. Particularly, FIG. 5 illustrates a partial cross-sectional structure of a display area that includes a plurality of subpixels (SP1, SP2 and SP3 of FIG. 5).

Referring to FIG. 5, an embodiment of the display panel 410 may include a semiconductor backplane SBP, a light emitting element backplane EBP, a light emitting element layer EML, an encapsulation layer TFE, a cover layer CVL, and a polarizing plate POL.

The semiconductor backplane SBP includes a semiconductor substrate SSUB including a plurality of pixel transistors PTR, a plurality of semiconductor insulating layers covering the plurality of pixel transistors PTR, and a plurality of contact terminals CTE electrically connected to the plurality of pixel transistors PTR.

The semiconductor substrate SSUB may be a silicon substrate, a germanium substrate or a silicon-germanium substrate. The semiconductor substrate SSUB may be a substrate doped with first type impurities. A plurality of well areas WA may be disposed on an upper surface of the semiconductor substrate SSUB. The plurality of well areas WA may be areas doped with second type impurities. The second type impurities may be different from the first type impurities. In an embodiment, for example, where the first type impurities are p-type impurities, the second type impurities may be n-type impurities. Alternatively, in an embodiment where the first type impurities are n-type impurities, the second type impurities may be p-type impurities.

In another embodiment, the semiconductor substrate SSUB may be replaced with a glass substrate or a polymer resin substrate such as polyimide. In such an embodiment, thin film transistors may be disposed on the glass substrate or the polymer resin substrate. The glass substrate may be a rigid substrate that is not bent, and the polymer resin substrate may be a flexible substrate that may be bent or curved.

Each of the plurality of well areas WA includes a source area SA corresponding to a source electrode of the pixel transistor PTR, a drain area DA corresponding to a drain electrode, and a channel area CH disposed between the source area SA and the drain area DA.

Each of the source area SA and the drain area DA may be doped with the first type impurities. A gate electrode GE of the pixel transistor PTR may overlap the well area WA in the third direction (Z-axis direction). The channel area CH may overlap the gate electrode GE in the third direction (Z-axis direction). The source area SA may be disposed at one side of the gate electrode GE, and the drain area SA may be disposed at the other side of the gate electrode GE.

A first semiconductor insulating layer SINS1 may be disposed on the semiconductor substrate SSUB. The first semiconductor insulating layer SINS1 may include or be formed of an inorganic layer of silicon carbon nitride (SiCN) or silicon oxide (SiOx), but the embodiment of the disclosure is not limited thereto.

A second semiconductor insulating layer SINS2 may be disposed on the first semiconductor insulating layer SINS1. The second semiconductor insulating layer SINS2 may may include or be formed of an inorganic layer of silicon oxide (SiOx), but the embodiment of the disclosure is not limited thereto.

The plurality of contact terminals CTE may be disposed on the second semiconductor insulating layer SINS2. Each of the plurality of contact terminals CTE may be connected to any one of the gate electrode GE, the source area SA and the drain area DA of each of the pixel transistors PTR through a hole defined through the first semiconductor insulating layer SINS1 and the second semiconductor insulating layer SINS2. The contact terminals CTE may include at least one selected from copper (Cu), aluminum (Al), tungsten (W), molybdenum (Mo), chromium (Cr), gold (Au), titanium (Ti), nickel (Ni) and neodymium (Nd), or an alloy thereof.

A third semiconductor insulating layer SINS3 may be disposed on sides of each of the plurality of contact terminals CTE. An upper surface of each of the plurality of contact terminals CTE may be exposed without being covered by the third semiconductor insulating layer SINS3. The third semiconductor insulating layer SINS3 may include or be formed of an inorganic layer of silicon oxide (SiOx), but the embodiment of the disclosure is not limited thereto.

The light emitting element backplane EBP includes first to eighth metal layers ML1 to ML8, reflective metal layers RL1 to RL4, a plurality of vias VA1 to VA10, and a terminal layer STPL. The light emitting element back plane EBP includes a plurality of interlayer insulating layers INS1 to INS10 disposed between the first to sixth metal layers ML1 to ML6.

The first to eighth metal layers ML1 to ML8 serve to implement a circuit of a subpixel SP by connecting the plurality of contact terminals CTE exposed from the semiconductor backplane SBP.

The first interlayer insulating layer INS1 may be disposed on the semiconductor backplane SBP. Each of the first vias VA1 may be connected to the contact terminal CTE exposed from the semiconductor backplane SBP by passing (or extending) through the first interlayer insulating layer INS1. Each of the first metal layers ML1 may be disposed on the first interlayer insulating layer INS1, and may be connected to the first via VA1.

The second interlayer insulating layer INS2 may be disposed on the first interlayer insulating layer INS1 and the first metal layers ML1. Each of the second vias VA2 may be connected to the first metal layer ML1 exposed by passing through the second interlayer insulating layer INS2. Each of the second metal layers ML2 may be disposed on the second interlayer insulating layer INS2, and may be connected to the second via VA2.

The third interlayer insulating layer INS3 may be disposed on the second interlayer insulating layer INS2 and the second metal layers ML2. Each of the third vias VA3 may be connected to the second metal layer ML2 exposed by passing through the third interlayer insulating layer INS3. Each of the third metal layers ML3 may be disposed on the third interlayer insulating layer INS3, and may be connected to the third via VA3.

The fourth interlayer insulating layer INS4 may be disposed on the third interlayer insulating layer INS3 and the third metal layers ML3. Each of the fourth vias VA4 may be connected to the third metal layer ML3 exposed by passing through the fourth interlayer insulating layer INS4. Each of the fourth metal layers ML4 may be disposed on the fourth interlayer insulating layer INS4, and may be connected to the fourth via VA4.

The fifth interlayer insulating layer INS5 may be disposed on the fourth interlayer insulating layer INS4 and the fourth metal layers ML4. Each of the fifth vias VA5 may be connected to the fourth metal layer ML4 exposed by passing through the fifth interlayer insulating layer INS5. Each of the fifth metal layers ML5 may be disposed on the fifth interlayer insulating layer INS5, and may be connected to the fifth via VA5.

The sixth interlayer insulating layer INS6 may be disposed on the fifth interlayer insulating layer ILD5 and the fifth metal layers ML5. Each of the sixth vias VA6 may be connected to the fifth metal layer ML5 exposed by passing through the sixth interlayer insulating layer INS6. Each of the sixth metal layers ML6 may be disposed on the sixth interlayer insulating layer INS6, and may be connected to the sixth via VA6.

The seventh interlayer insulating layer INS7 may be disposed on the sixth interlayer insulating layer INS6 and the sixth metal layers ML6. Each of the seventh vias VA7 may be connected to the sixth metal layer ML6 exposed by passing through the seventh interlayer insulating layer INS7. Each of the seventh metal layers ML7 may be disposed on the seventh interlayer insulating layer INS7, and may be connected to the seventh via VA7.

The eighth interlayer insulating layer INS8 may be disposed on the seventh interlayer insulating layer INS7 and the seventh metal layers ML7. Each of the eighth vias VA8 may be connected to the seventh metal layer ML7 exposed by passing through the eighth interlayer insulating layer INS8. Each of the eighth metal layers ML8 may be disposed on the eighth interlayer insulating layer INS8, and may be connected to the eighth via VA8.

The first to eighth metal layers ML1 to ML8 and the first to eighth vias VA1 to VA8 may include substantially a same material as each other. The first to eighth metal layers ML1 to ML8 and the first to eighth vias VA1 to VA8 may include at least one selected from copper (Cu), aluminum (Al), tungsten (W), molybdenum (Mo), chromium (Cr), gold (Au), titanium (Ti), nickel (Ni) and neodymium (Nd), or an alloy thereof. The first to eighth vias VA1 to VA8 may include substantially a same material as each other. The first to eighth interlayer insulating layers INS1 to INS8 may include or be formed of inorganic layers of silicon oxide (SiOx), but the embodiment of the disclosure is not limited thereto.

A thickness of the first metal layer ML1, a thickness of the second metal layer ML2, a thickness of the third metal layer ML3, a thickness of the fourth metal layer ML4, a thickness of the fifth metal layer ML5 and a thickness of the sixth metal layer ML6 may be greater than a thickness of the first via VA1, a thickness of the second via VA2, a thickness of the third via VA3, a thickness of the fourth via VA4, a thickness of the fifth via VA5 and a thickness of the sixth via VA6, respectively. Each of the thickness of the second metal layer ML2, the thickness of the third metal layer ML3, the thickness of the fourth metal layer ML4, the thickness of the fifth metal layer ML5 and the thickness of the sixth metal layer ML6 may be greater than the thickness of the first metal layer ML1. The thickness of the second metal layer ML2, the thickness of the third metal layer ML3, the thickness of the fourth metal layer ML4, the thickness of the fifth metal layer ML5 and the thickness of the sixth metal layer ML6 may be substantially the same as one another.

Each of a thickness of the seventh metal layer ML7 and a thickness of the eighth metal layer ML8 may be greater than each of the thickness of the first metal layer ML1, the thickness of the second metal layer ML2, the thickness of the third metal layer ML3, the thickness of the fourth metal layer ML4, the thickness of the fifth metal layer ML5 and the thickness of the sixth metal layer ML6. Each of the thickness of the seventh metal layer ML7 and the thickness of the eighth metal layer ML8 may be greater than each of the thickness of the seventh via VA7 and the thickness of the eighth via VA8. Each of the thickness of the seventh via VA7 and the thickness of the eighth via VA8 may be greater than each of the thickness of the first via VA1, the thickness of the second via VA2, the thickness of the third via VA3, the thickness of the fourth via VA4, the thickness of the fifth via VA5 and the thickness of the sixth via VA6. The thickness of the seventh metal layer ML7 and the thickness of the eighth metal layer ML8 may be substantially the same as each other.

The ninth interlayer insulating layer INS9 may be disposed on the eighth interlayer insulating layer INS8 and the eighth metal layers ML8. The ninth interlayer insulating layer INS9 may include or be formed of an inorganic layer of silicon oxide (SiOx), but the embodiment of the disclosure is not limited thereto.

Each of the ninth vias VA9 may be connected to the eighth metal layer ML8 exposed by passing through the ninth interlayer insulating layer INS9. The ninth vias VA9 may include or be made of at least one selected from copper (Cu), aluminum (Al), tungsten (W), molybdenum (Mo), chromium (Cr), gold (Au), titanium (Ti), nickel (Ni) and neodymium (Nd), or an alloy thereof.

Each of the first reflective electrodes RL1 may be disposed on the ninth interlayer insulating layer INS9. The first reflective electrodes RL1 may include or be made of at least one selected from copper (Cu), aluminum (Al), tungsten (W), molybdenum (Mo), chromium (Cr), gold (Au), titanium (Ti), nickel (Ni) and neodymium (Nd), or an alloy thereof.

Each of the second reflective electrodes RL2 may be disposed on the first reflective electrode RL1. The second reflective electrodes RL2 may include or be made of at least one selected from copper (Cu), aluminum (Al), tungsten (W), molybdenum (Mo), chromium (Cr), gold (Au), titanium (Ti), nickel (Ni) and neodymium (Nd), or an alloy thereof. In an embodiment, for example, the second reflective electrodes RL2 may include or be formed of titanium nitride (TiN).

A stepped layer STPL may be disposed on the second reflective electrode RL2 at a portion that overlaps the first subpixel SP1. The stepped layer STPL may not be disposed at a portion that overlaps the second subpixel SP2 and the third subpixel SP3. The stepped layer STPL may include or be formed of an inorganic layer of carbon nitride (SiCN) or silicon oxide (SiOx), but the embodiment of the disclosure is not limited thereto.

The third reflective electrode RL3 may be disposed on the second reflective electrode RL2 and the stepped layer STPL at a portion that overlaps the first subpixel SP1. The third reflective electrode RL3 may be disposed on the second reflective electrode RL2 at a portion that overlaps the second subpixel SP2 and the third subpixel SP3. The third reflective electrodes RL3 may include or be made of at least one selected from copper (Cu), aluminum (Al), tungsten (W), molybdenum (Mo), chromium (Cr), gold (Au), titanium (Ti), nickel (Ni) and neodymium (Nd), or an alloy thereof. In another embodiment, at least one selected from the first reflective electrode RL1, the second reflective electrode RL2 or the third reflective electrode RL3 may be omitted.

Each of the fourth reflective electrodes RL4 may be disposed on the third reflective electrode RL3. The fourth reflective electrode RL4 may include metal having high reflectance to be advantageous for reflecting light. The fourth reflective electrode RL4 may include or be formed of aluminum (Al), a stacked structure (Ti/Al/Ti) of aluminum and titanium, a stacked structure (ITO/AI/ITO) of aluminum and ITO, APC alloy of silver (Ag), palladium (Pd) and copper (Cu), or a stacked structure (ITO/APC/ITO) of APC alloy and ITO, but the embodiment of the disclosure is not limited thereto.

The tenth interlayer insulating layer INS10 may be disposed on the ninth interlayer insulating layer INS9 and the fourth reflective electrode RL4. The tenth interlayer insulating layer INS10 may include or be formed of an inorganic layer of silicon oxide (SiOx), but the embodiment of the disclosure is not limited thereto.

Each of the tenth vias VA10 may be connected to the ninth metal layer ML9 exposed by passing through the tenth interlayer insulating layer INS10. The tenth vias VA10 may include or be made of at least one selected from copper (Cu), aluminum (Al), tungsten (W), molybdenum (Mo), chromium (Cr), gold (Au), titanium (Ti), nickel (Ni) and neodymium (Nd), or an alloy thereof. Due to the stepped layer STPL, a thickness of the tenth via VA10 in the first subpixel SP1 may be smaller than a thickness of the tenth via VA10 in each of the second subpixel SP2 and the third subpixel SP3.

The light emitting element layer EML may be disposed on the light emitting element backplane EBP. The light emitting element layer EML may include light emitting elements LE including a first electrode AND, a light emitting layer IL and a second electrode CAT, respectively, and a pixel defining layer PDL.

The first electrode AND may be disposed on the tenth interlayer insulating layer INS10, and may be connected to the tenth via VA10. The first electrode AND may be connected to the drain area DA or the source area SA of the pixel transistor PTR through the tenth via VA10, the first to fourth reflective electrodes RL1 to RL4, the first to ninth vias VA1 to VA9, the first to eighth metal layers ML1 to ML8 and the contact terminal CTE. The first electrode AND may include or be made of at least one selected from copper (Cu), aluminum (Al), tungsten (W), molybdenum (Mo), chromium (Cr), gold (Au), titanium (Ti), nickel (Ni) and neodymium (Nd), or an alloy thereof. In an embodiment, for example, the first electrode AND may include or be formed of titanium nitride (TiN).

The pixel defining layer PDL may be disposed on a partial area of the first electrode AND. The pixel defining layer PDL may cover an edge of the first electrode AND. The pixel defining layer PDL serves to partition the first light emission areas EA1, the second light emission areas EA2 and the third light emission areas EA3.

The first light emission area EA1 may be defined as an area in which the first electrode AND, the first light emitting layer IL1 and the second electrode CAT are sequentially stacked in the first subpixel SP1 to emit light. The second light emission area EA2 may be defined as an area in which the first electrode AND, the second light emitting layer IL2 and the second electrode CAT are sequentially stacked in the second subpixel SP2 to emit light. The third light emission area EA3 may be defined as an area in which the first electrode AND, the third light emitting layer IL3 and the second electrode CAT are sequentially stacked in the third subpixel SP3 to emit light.

The pixel defining layer PDL may include first to third pixel defining layers PDL1, PDL2 and PDL3. The first pixel defining layer PDL1 may be disposed on the edge of the first electrode AND, the second pixel defining layer PDL2 may be disposed on the first pixel defining layer PDL1, and the third pixel defining layer PDL3 may be disposed on the second pixel defining layer PDL2. The first pixel defining layer PDL1, the second pixel defining layer PDL2 and the third pixel defining layer PDL3 may include or be formed of an inorganic layer of silicon oxide (SiOx), but the embodiment of the disclosure is not limited thereto.

The light emitting layer IL may include a first light emitting layer IL1, a second light emitting layer IL2 and a third light emitting layer IL3. The first light emitting layer IL1, the second light emitting layer IL2 and the third light emitting layer IL3 may emit light of different colors from each other. In an embodiment, for example, the first light emitting layer IL1 may emit red light, the second light emitting layer IL2 may emit green light, and the third light emitting layer IL3 may emit blue light, but the embodiment of the disclosure is not limited thereto.

The first to third light emitting layers IL1, IL2 and IL3 disposed to be adjacent to one another in the first direction (X-axis direction) may be disconnected by the pixel defining layer PDL. In the display panel 410 according to an embodiment, the first to third light emitting layers IL1, IL2 and IL3 disposed to be adjacent to one another may be disconnected from each other, thereby effectively preventing a leakage current between the adjacent subpixels SP1, SP2 and SP3 and effectively preventing color interference.

The second electrode CAT may be disposed on the light emitting layer IL. The second electrode CAT may be a common electrode. The second electrode CAT may include or be formed of a transparent conductive material TCO, such as an ITO or an IZO, which is capable of transmitting light, or a semi-transmissive conductive material such as magnesium (Mg), silver (Ag) or an alloy of magnesium (Mg) and silver (Ag). In an embodiment where the second electrode CAT includes or is formed of a semi-transmissive metal material, light emission efficiency in each of the first to third subpixels SP1, SP2 and SP3 may be increased by a micro cavity.

The encapsulation layer TFE may be disposed on the light emitting element layer EML. The encapsulation layer TFE may include at least one inorganic layer to prevent oxygen or moisture from being permeated into the light emitting element layer EML. In an embodiment, for example, the encapsulation layer TFE may include a first encapsulation layer TFE1 and a second encapsulation layer TFE2.

The first encapsulation layer TFE1 may be disposed on the second electrode CAT, and the second encapsulation layer TFE2 may be disposed on the first encapsulation layer TFE1. The first encapsulation layer TFE1 and the second encapsulation layer TFE2 may be formed of or defined by a multi-layer in which one or more inorganic layers of silicon nitride (SiNx), silicon oxynitride (SiON), silicon oxide (SiOx), titanium oxide (TiOx) and aluminum oxide (AlOx) are alternately stacked.

An adhesive layer APL may be a layer for enhancing surface adhesion between the encapsulation layer TFE and the cover layer CVL. The adhesive layer APL may be an organic layer such as a layer including at least one selected from an acrylic resin, an epoxy resin, a phenolic resin, a polyamide resin and a polyimide resin.

The cover layer CVL may be disposed on the adhesive layer APL. The cover layer CVL may be a glass substrate or a polymer resin such as a resin. In an embodiment where the cover layer CVL is a glass substrate, the cover layer CVL may serve as an encapsulation substrate. In an embodiment where the cover layer CVL is a polymer resin such as a resin, the cover layer CVL may be directly coated on the adhesive layer APL.

The polarizing plate POL may be disposed on one surface of the cover layer CVL. The polarizing plate POL may be a structure for preventing deterioration of visibility, which is caused by reflection of external light. The polarizing plate POL may include a linear polarizing plate and a phase delay film. In an embodiment, for example, the phase delay film may be a quarter-wave plate (λ/4 plate), but the embodiment of the disclosure is not limited thereto.

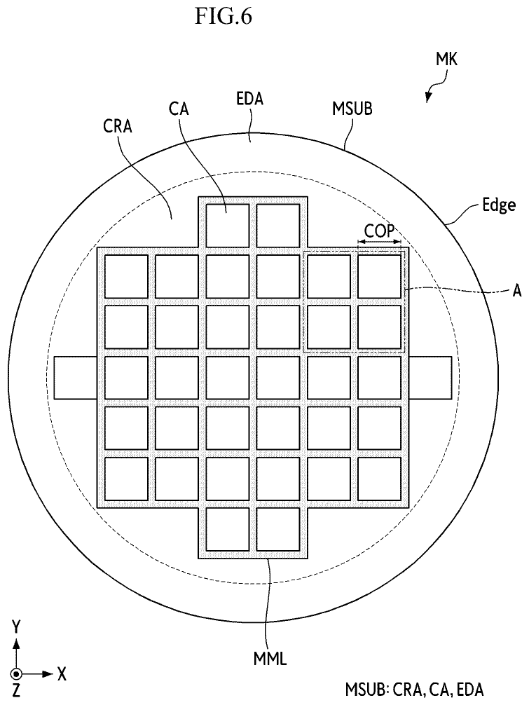

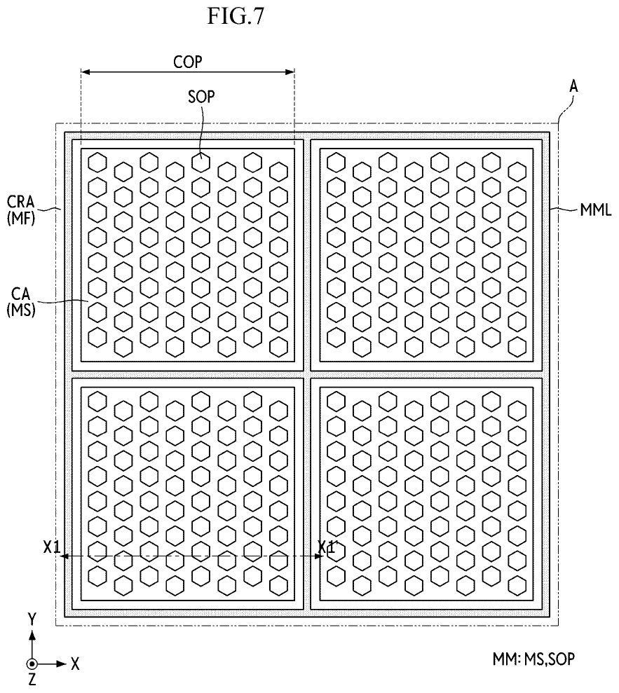

FIG. 6 is a schematic plan view of a mask according to an embodiment. FIG. 7 is an enlarged plan view of an area A in FIG. 6. The mask according to an embodiment shown in FIG. 6 may be used in a process of depositing at least a portion of the light emitting layer IL of the display panel 410 described with reference to FIG. 5.

Referring to FIGS. 6 and 7, a mask MK according to an embodiment may be a mask used to manufacture an ultra-high resolution display. For example, the mask MK may be a mask used to manufacture a display included in an extended reality device (XR device), such as a VR device, an AR device and an MR device.

The mask MK according to an embodiment may be used to perform a deposition process of the subpixels (SP1, SP2 and SP3 of FIG. 5) for a silicon wafer rather than a large-sized substrate used for a display of the related art. In case of a display included in the extended reality device, since a screen is positioned directly in front of a user's eyes, the display may have a smaller screen than a large size. Also, since the screen is positioned to be close to the user's eyes, the display may be desired to have ultra-high resolution. For example, the desired resolution of the display included in the extended reality device may be about 1000 PPI or greater, e.g., 2000 PPI or greater. Therefore, the deposition mask MK according to an embodiment may be a mask used to manufacture such an ultra-high resolution display. The mask MK according to embodiments may include various embodiments of mask MK1, MK3, MK5, MK7, MK9, MK11 and MK13 that will be described below.

The mask MK according to an embodiment may include a mask substrate MSUB.

The mask substrate MSUB according to an embodiment may include a silicon wafer. Since a fine and precise process is possible for the silicon wafer as compared with a large-sized substrate by utilizing a technology developed in a semiconductor process, the silicon wafer may be employed as a substrate for an ultra-high resolution display. The mask MK according to an embodiment may use the silicon wafer in the same manner to form a pixel on the silicon wafer of the ultra-high resolution display.

The mask substrate MSUB according to an embodiment may have a shape corresponding to the silicon wafer of the ultra-high resolution display. For example, the mask substrate MSUB may have a same size or a same shape as the silicon wafer of the ultra-high resolution display, but is not limited thereto. The mask substrate MSUB may include a large-sized substrate. In an embodiment, for example, the mask substrate MSUB may include a material such as glass, quartz or a polymer resin.

The mask substrate MSUB according to an embodiment may include a plurality of cell areas CA, a cell peripheral area CRA and an edge area EDA.

The cell peripheral area CRA according to an embodiment may be disposed to surround the plurality of cell areas CA. The cell peripheral area CRA may be an area overlapped with a mask frame MF. The cell peripheral area CRA may be a portion that overlaps a cell cut line in a subsequent process.

On a plane (or in a plan view or when viewed in the Z-axis direction), the mask frame MF may define a mask opening COP, and may be positioned to surround the mask opening COP. The mask frame MF may be an area that supports the mask MK. Here, the Z-axis direction may be a thickness direction of the mask MK. A structure of the mask frame MF will be described later.

According to an embodiment, the plurality of cell areas CA may be formed, and may be positioned to be spaced apart from each other. The cell area CA may be a portion positioned to overlap the mask opening COP. On the plane, the cell area CA may be an area overlapped with a mask membrane MM. The mask membrane MM may include a pixel opening SOP and a mask shadow MS.

On the plane, the mask shadow MS may be integrally formed while entirely surrounding the pixel opening SOP, and the mask frame MF may be integrally formed while entirely surrounding the mask shadow MS. In other words, on the plane, the mask shadow MS may be in the form of one pattern integrally configured while exposing the pixel opening SOP, and the mask frame MF may be in the form of one pattern integrally configured while exposing the mask opening COP.

The edge area EDA according to an embodiment may be an edge of the mask substrate MSUB and an area surrounding the edge of the mask substrate MSUB. In other words, the edge area EDA may mean an outer portion of the mask substrate MSUB.

A mask metal layer MML according to an embodiment may be positioned at a portion that overlaps the cell peripheral area CRA. On the plane, the mask metal layer MML may be positioned to surround the mask opening COP. The mask metal layer MML may not overlap the cell area CA, and may overlap the edge area EDA.

On the plane, the mask metal layer MML may be in the form of one pattern integrally configured while exposing the mask opening COP. In other words, the mask metal layer MML may have a mesh shape while exposing the mask opening COP.

The mask metal layer MML according to an embodiment may resolve a defect in a tight adhesion to the display panel 410 due to warpage of the mask MK. Details thereof will be described later.

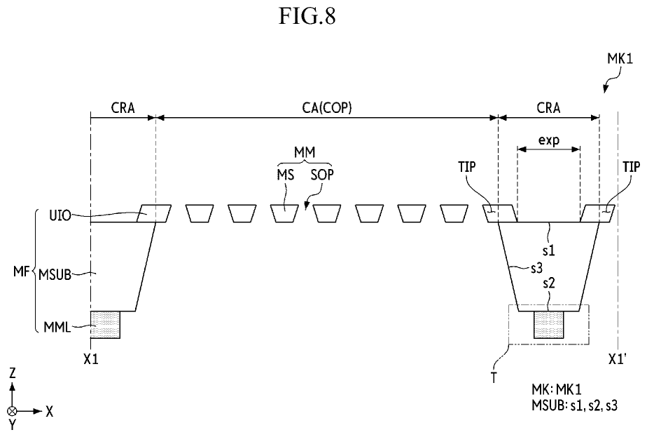

FIG. 8 is a cross-sectional view taken along line X1-X1′ in FIG. 7.

Referring to FIG. 8, on the cross-section, the mask frame MF according to an embodiment may be positioned at a portion that overlaps the cell peripheral area CRA. The mask frame MF may include a mask substrate MSUB, a mask inorganic layer UIO and a mask metal layer MML.

The mask substrate MSUB according to an embodiment may include an upper surface s1, a lower surface s2 and a side surface s3. The upper surface s1 may be one surface directed toward a mask inorganic layer UIO, the lower surface s2 may be one surface facing the upper surface s1, and the side surface s3 may be one surface connecting the upper surface s1 with the lower surface s2.

The side surface s3 of the mask substrate MSUB may be an inclined surface. This may be caused by removing a portion of the mask substrate MSUB by an etching process in a manufacturing process of the mask MK1.

The mask inorganic layer UIO according to an embodiment may be positioned on the mask substrate MSUB. The mask inorganic layer UIO may be in contact with the upper surface s1 of the mask substrate MSUB. The mask inorganic layer UIO may be positioned to surround an exposed portion exp included in the upper surface s1 of the mask substrate MSUB. In the manufacturing process of the mask MK1, the mask inorganic layer UIO may be formed to entirely cover the upper surface s1 of the mask substrate MSUB and then a portion thereof may be removed by a subsequent etching process. Thus, the upper surface s1 of the mask substrate MSUB may include the exposed portion exp.

The mask inorganic layer UIO may include a tip TIP protruded toward the cell area CA rather than the side s3 of the mask substrate MSUB. The tip TIP of the mask inorganic layer UIO may be positioned at a portion that overlaps the cell area CA. The tip TIP of the mask inorganic layer UIO may be spaced apart from the mask shadow MS with the pixel opening SOP interposed therebetween.

The mask inorganic layer UIO may include an inorganic insulating material. In an embodiment, for example, the mask inorganic layer UIO may include at least one selected from silicon oxide, silicon nitride and silicon oxynitride.

The mask metal layer MML according to an embodiment may be positioned at a portion that overlaps the cell peripheral area CRA. The mask metal layer MML may be positioned on the lower surface s2 of the mask substrate MSUB, and may be in contact with the lower surface s2 of the mask substrate MSUB. The mask metal layer MML may be positioned at a portion that overlaps the exposed portion exp included in the upper surface s1 of the mask substrate MSUB in the third direction (Z-axis direction).

The mask metal layer MML may not overlap the cell area CA. In other words, the mask metal layer MML may not overlap the tip TIP of the mask inorganic layer UIO in the third direction (Z-axis direction).

The mask metal layer MML may include metal. In an embodiment, for example, the mask metal layer MML may include or be made of at least one selected from copper (Cu), aluminum (Al), tungsten (W), molybdenum (Mo), chromium (Cr), gold (Au), titanium (Ti), nickel (Ni) and neodymium (Nd), or an alloy thereof.

In general, a mask including or formed of silicon may have warpage by itself. Warpage may mean self-bending included in the mask. For example, warpage of the mask may deteriorate a tight adhesion between the display panel 410 and the mask MK1, and may cause a deposition defect of the display panel 410.

The mask MK1 included in an embodiment may include the mask metal layer MML on the lower surface s2 of the mask substrate MSUB, thereby planarizing a warpage portion of the mask substrate MSUB. In detail, the mask MK1 according to an embodiment may planarize the warpage portion of the mask substrate MSUB by radiating a laser to the mask metal layer MML and melting and condensing a portion of the mask metal layer MML in the manufacturing process of the mask MK1.

The mask membrane MM according to an embodiment may be positioned at a portion that overlaps the cell area CA. The mask membrane MM may include a plurality of mask shadows MS and a pixel opening SOP.

The pixel opening SOP may be positioned between a plurality of mask shadows MS adjacent to each other. The pixel opening SOP may be referred to as a “hole” or a “mask hole”. A plurality of pixel openings SOP may be defined through the mask frame MF along a thickness direction (e.g., the third direction (Z-axis direction) of the mask MK1. The plurality of pixel openings SOP may be formed by etching a portion of the mask inorganic layer UIO and the mask substrate MSUB from a direction of the lower surface s2 of the mask substrate MSUB in the manufacturing process of the mask MK1.

The mask shadow MS according to an embodiment may be positioned to surround the pixel opening SOP. A plurality of mask shadows MS may serve as a blocking portion for masking a substrate to be deposited (e.g., the display panel 410 or the backplane substrate) when a deposition material is evaporated from a deposition source inside a depositor. Therefore, the deposition material generated from the deposition source may be deposited on a surface of the substrate to be deposited (e.g., the display panel 410 or the backplane substrate) through the pixel opening SOP.

The mask shadow MS may include a same material as that of the mask inorganic layer UIO. In the manufacturing process of the mask MK1, the mask inorganic layer UIO and the mask shadow MS may be integrally formed and then formed to be spaced apart from each other with the pixel opening SOP interposed therebetween by a subsequent etching process.

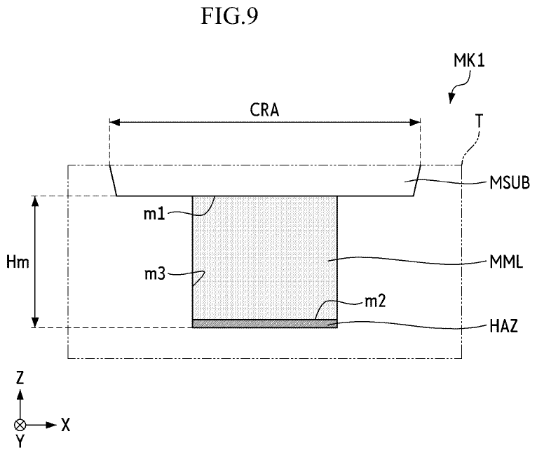

FIG. 9 is an enlarged cross-sectional view of an area T in FIG. 8.

Referring to FIG. 9, the mask metal layer MML may include an upper surface m1, a lower surface m2 and a side surface m3. The upper surface m1 may be one surface directed toward the mask substrate MSUB, the lower surface m2 may be one surface facing the upper surface m1, and the side surface m3 may be one surface connecting the upper surface m1 with the lower surface m2.

In an embodiment, the mask metal layer MML may include a heat-affected portion HAZ on the lower surface m2 of the mask metal layer MML. The heat-affected portion HAZ may be a mark in which a portion of the lower surface m2 of the mask metal layer MML is carbonized by a high-temperature laser, but is not limited thereto. According to another embodiment, the metal layer MML may not include the heat-affected portion HAZ. The high-temperature laser included in the manufacturing process of the mask MK1 may include a nanosecond laser and a picosecond laser.

The heat-affected portion HAZ included in the mask MK1 may include various shapes. In an embodiment, for example, the heat-affected portion HAZ may have any shape affected by the laser, such as a smoked shape, a corrugated shape and an embossed shape. The shape of the heat-affected portion HAZ will be described later.

A height Hm (or a thickness in the third direction or the Z-axis direction) of the mask metal layer MML according to an embodiment may be about 500 nanometers or greater.

The mask MK1 according to an embodiment may improve a tight adhesion to the display panel 410, thereby resolving the deposition defect of the display panel 410. In an embodiment, as described above, the mask MK1 may planarize the warpage portion of the mask substrate MSUB by radiating a laser to the mask metal layer MML, which overlaps the warpage portion of the mask substrate MSUB, and melting and condensing a portion of the mask metal layer MML in the manufacturing process. In such an embodiment, the laser may be radiated toward the lower surface m2 of the mask metal layer MML by the laser process included in the manufacturing process of the mask MK1. Therefore, the mask metal layer MML included in the mask MK1 may include a heat-affected portion HAZ on the lower surface m2, but is not limited thereto.

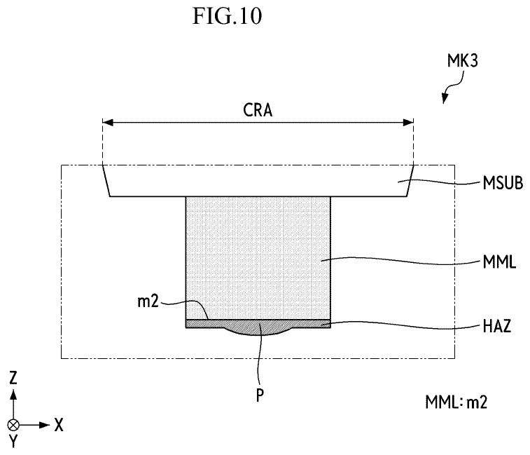

FIGS. 10 to 12 are enlarged cross-sectional views of an area T in FIG. 8, according to other embodiments. Hereinafter, any repetitive detailed description of a same or like elements as those of the mask MK1 described above will be omitted, and differences from the mask MK1 described above will be described.

Referring to FIG. 10, in an embodiment, the mask metal layer MML included in the mask MK3 may include a heat-affected portion HAZ on the lower surface m2 of the mask metal layer MML. The heat-affected portion HAZ included in the mask MK3 may include a protrusion P in which a portion of the lower surface m2 of the mask metal layer MML is protruded toward the other side in the third direction (Z-axis direction). The protrusion P may be a mark in which a portion of the lower surface m2 of the mask metal layer MML is carbonized by a high-temperature laser. The shape of the heat-affected portion HAZ may include various shapes in accordance with the intensity, size, frequency and the like of the laser used in the manufacturing process.

Although an embodiment where the heat-affected portion HAZ included in the mask metal layer MML includes a single protrusion P is shown in FIG. 10, the disclosure is not limited thereto. In another embodiment, the mask metal layer MML included in the mask MK3 may include a plurality of protrusions P.

It may be seen that the mask MK3 according to an embodiment includes a heat-affected portion HAZ in which a portion of the lower surface m2 of the mask metal layer MML has a protrusion P, and thus the manufacturing process of the mask MK3 includes a laser processing process performed in a direction of the lower surface m2 of the mask metal layer MML. Any repetitive detailed description of the same or like elements as those described above will be omitted.

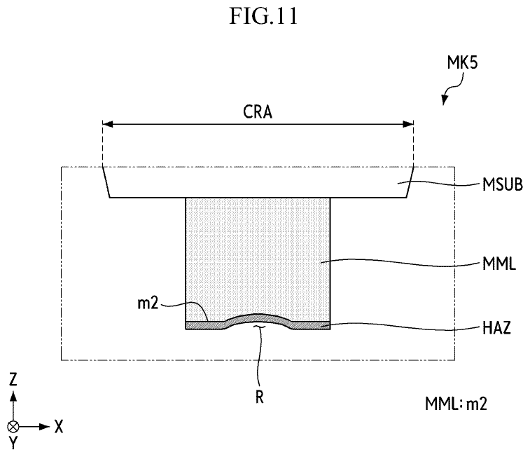

Referring to FIG. 11, in another embodiment, the mask metal layer MML included in the mask MK5 may include a heat-affected portion HAZ. The heat-affected portion HAZ included in the mask MK5 may include a recess R in which a portion of the lower surface m2 of the mask metal layer MML is recessed toward one side in the third direction (Z-axis direction). The recess R may be a mark in which a portion of the lower surface m2 of the mask metal layer MML is carbonized by a high-temperature laser.

Although the heat-affected portion HAZ included in the mask metal layer MML is shown as including a single recess R, the disclosure is not limited thereto. The mask metal layer MML included in the mask MK5 may include a plurality of recesses R.

It may be seen that the mask MK5 according to an embodiment includes a heat-affected portion HAZ in which a portion of the lower surface m2 of the mask metal layer MML has a recess R, and thus the manufacturing process of the mask MK5 includes a laser processing process performed in a direction of the lower surface m2 of the mask metal layer MML

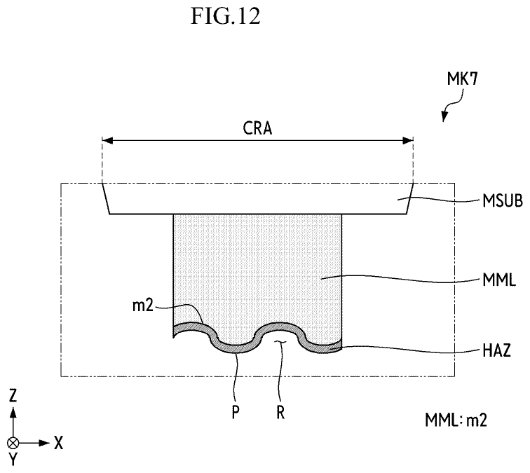

Referring to FIG. 12, in another embodiment, the mask metal layer MML included in the mask MK7 may include a heat-affected portion HAZ. The heat-affected portion HAZ included in the mask MK7 may include a recess R in which a portion of the lower surface m2 of the mask metal layer MML is recessed toward one side in the third direction (Z-axis direction) and a protrusion P protruded toward the other side in the third direction (Z-axis direction). The recess R and the protrusion P may be alternately formed in the heat-affected portion HAZ of the mask metal layer MML included in the mask MK7. The recess R and the protrusion P may be a mark in which a portion of the lower surface m2 of the mask metal layer MML is carbonized by a high-temperature laser.

It may be seen that the mask MK7 according to an includes a heat-affected portion HAZ in which a portion of the lower surface m2 of the mask metal layer MML has both a recess R and a protrusion P and thus the manufacturing process of the mask MK7 includes a laser processing process performed in a direction of the lower surface m2 of the mask metal layer MML. Any repetitive detailed description of the same or like elements as those described above will be omitted.

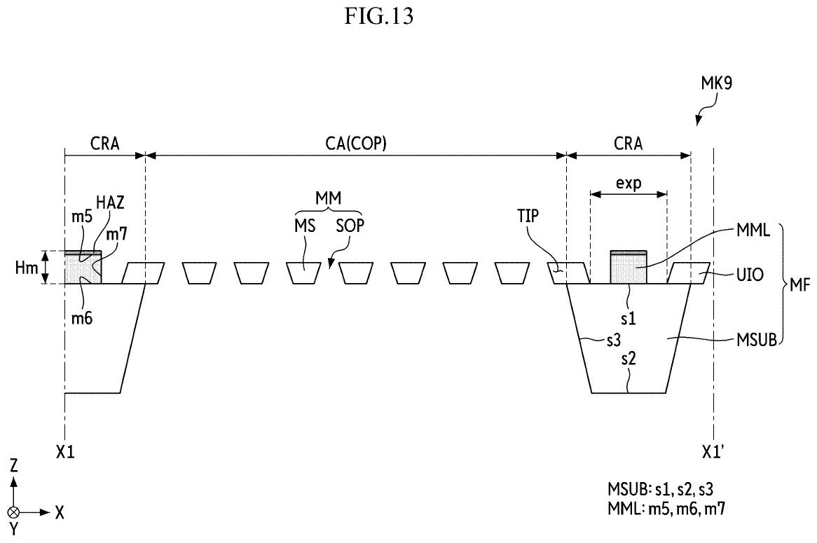

FIG. 13 is a cross-sectional view taken along line X1-X1′ in FIG. 7, according to another embodiment.

The mask MK9 shown in FIG. 13 is substantially the same as the mask MK1 shown in FIG. 8 except that the metal layer MML included in the mask MK9 is positioned on the upper surface s1 of the mask substrate MSUB. Differences between the mask MK9 shown in FIG. 13 and the mask MK1 shown in FIG. 8 will be described later.

The mask frame MF included in the mask MK9 may include a mask substrate MSUB, a mask inorganic layer UIO and a mask metal layer MML. The mask metal layer MML may be positioned on the upper surface s1 of the mask substrate MSUB, and may be in contact with the upper surface s1 of the mask substrate MSUB. The mask metal layer MML included in the mask MK9 may be positioned in contact with the exposed portion exp of the upper surface s1 of the mask substrate MSUB.

The mask metal layer MML included in the mask MK9 may be spaced apart from the mask inorganic layer UIO in the first direction (X-axis direction). In other words, the mask inorganic layer UIO included in the mask MK9 may be positioned to be spaced apart from the mask metal layer MML, and the mask inorganic layer UIO may also surround the mask metal layer MML.

The mask metal layer MML included in the mask MK9 may be positioned on a same plane as the mask inorganic layer UIO and the mask membrane MM in the first direction (X-axis direction). In other words, the mask metal layer MML included in the mask MK9 may be positioned on a same plane as the mask shadow MS in the first direction (X-axis direction). The height Hm of the mask metal layer MML may be about 500 nanometers or greater. Any repetitive detailed description of the same or like elements as those described above will be omitted.

In an embodiment, the mask metal layer MML may include an upper surface m5, a lower surface m6 and a side surface m7. The lower surface m6 may be one surface directed toward the mask substrate MSUB, the upper surface m5 may be one surface facing the lower surface m6, and the side surface m7 may be one surface connecting the upper surface m5 with the lower surface m6.

In such an embodiment, the mask metal layer MML may include a heat-affected portion HAZ on the upper surface m5 of the mask metal layer MML, but is not limited thereto. According to another embodiment, the mask metal layer MML may not include a heat-affected portion HAZ.

The heat-affected portion HAZ may be a mark in which a portion of the upper surface m5 of the mask metal layer MML is carbonized by a high-temperature laser. The heat-affected portion HAZ may include various shapes. In an embodiment, for example, the shape of the heat-affected portion HAZ may be any shape affected by the laser, such as a smoked shape, a corrugated shape, a shape with a protrusion and a shape with a recess.

The mask MK9 may planarize the warpage portion of the mask substrate MSUB by radiating a laser to the mask metal layer MML, which overlaps the warpage portion of the mask substrate MSUB, and melting and condensing a portion of the mask metal layer MML in the manufacturing process. In such an embodiment, the laser may be radiated toward the upper surface m5 of the mask metal layer MML by the laser process included in the mask MK9. Therefore, the mask metal layer MML included in the mask MK9 may include a heat-affected portion HAZ on the upper surface m5, but is not limited thereto. Therefore, the mask MK9 according to an embodiment may improve a tight adhesion to the display panel 410, thereby resolving the deposition defect of the display panel 410.

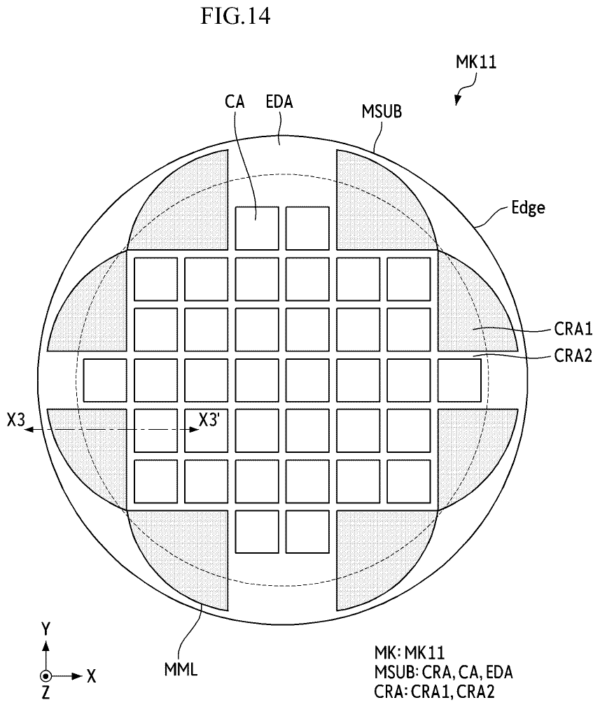

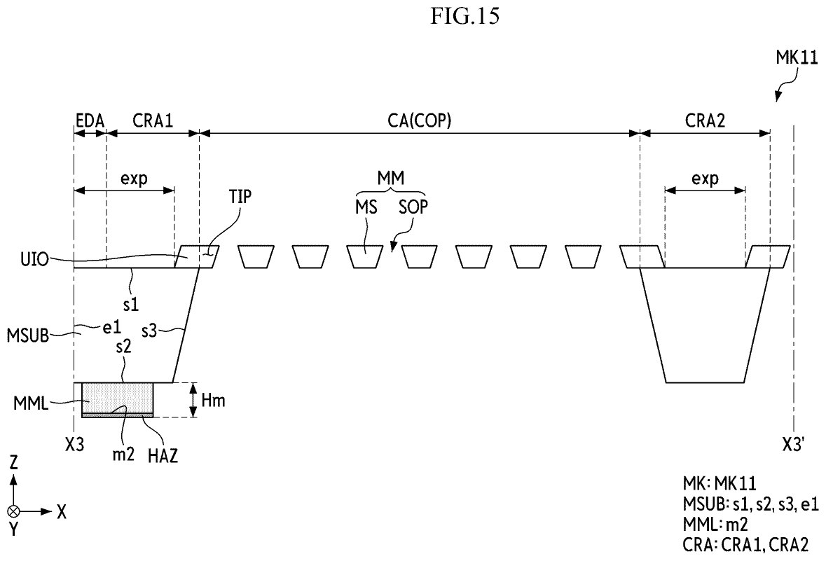

FIG. 14 is a schematic plan view of a mask according to another embodiment. FIG. 15 is a cross-sectional view taken along line X3-X3′ in FIG. 14.

Referring to FIG. 14, in an embodiment, the mask substrate MSUB included in the mask MK11 on a plane may include a cell area CA, a cell peripheral area CRA and an edge area EDA. The cell peripheral area CRA of the mask substrate MSUB included in the mask MK11 may include a first cell peripheral area CRA1 and a second cell peripheral area CRA2.

The cell area CA and the edge area EDA, which are included in the mask MK11, may have a same structure and characteristics as those of the cell area CA and the edge area EDA, which are included in the mask MK1. Hereinafter, any repetitive detailed description of the same or like elements as those of the mask MK1 described above with reference to FIGS. 6 to 8 will be omitted, and differences from the mask MK1 shown in FIGS. 6 to 8 will be described.

In an embodiment, the first cell peripheral area CRA1 included in the mask MK11 may be an area that overlaps the mask metal layer MML, and the second cell peripheral area CRA2 may be an area that does not overlap the mask metal layer MML.

The mask metal layer MML included in the mask MK11 may be intensively positioned at a portion that overlaps the edge area EDA and the first cell peripheral area CRA1. The mask metal layer MML may not overlap the cell area CA and the second cell peripheral area CRA2.

The mask metal layer MML included in the mask MK11 may be formed as a plurality of mask metal layers. The plurality of mask metal layers MML may be formed to surround the outer portion of the cell area CA. Although an embodiment where the mask metal layer MML is in a fan shape on a plane (or when viewed in a plan view or in the third direction. i.e., the Z-axis direction) is shown in FIG. 14, the disclosure is not limited thereto. In another embodiment, the mask metal layer MML may have various shapes such as a circular shape, a rectangular shape and a polygonal shape on a plane.

The mask metal layer MML included in the mask MK11 may solve a defect in a tight adhesion to the display panel 410 due to warpage of the mask MK. Details thereof will be described later.

Referring to FIG. 15, the mask MK11 may include a mask membrane MM at a portion that overlaps the cell area CA, and the mask membrane MM may include a pixel opening SOP and a mask shadow MS surrounding the pixel opening SOP. In addition, the mask MK11 may include a mask substrate MSUB and a mask inorganic layer UIO at a portion that overlaps the cell peripheral area CRA. A structure and characteristics of the mask substrate MSUB, the mask inorganic layer UIO and the mask membrane MM, which are included in the mask MK11, may be the same as those of the mask MK1. Hereinafter, differences between the mask MK1 shown in FIGS. 6 to 8 and the mask MK11 shown in FIGS. 14 and 15 will be described.

In an embodiment, as shown in FIGS. 14 and 15, The mask MK11 may include a mask substrate MSUB, a mask inorganic layer UIO and a mask metal layer MML at a portion that overlaps the edge area EDA and the first cell peripheral area CRA1.

The mask substrate MSUB included in the mask MK11 may further include an edge surface el positioned at a portion that overlaps the edge area EDA, in addition to the upper surface s1, the lower surface s2 and the side surface s3. The edge surface e1 may mean an edge of the mask MK shown in FIG. 14. The edge surface e1 may connect the upper surface s1 with the lower surface s2 at a portion that overlaps the edge area EDA.

The upper surface s1 of the mask substrate MSUB included in the mask MK11 may include an exposed portion exp at a portion that overlaps the edge area EDA and the cell peripheral area CRA. The exposed portion exp may mean a portion of the upper surface s1 of the mask substrate MSUB, which is not covered by the mask inorganic layer UIO.

The mask inorganic layer UIO included in the mask MK11 may be positioned at a portion that overlaps the first cell peripheral area CRA1 and the second cell peripheral area CRA2. The mask inorganic layer UIO may not overlap the edge area EDA. The mask inorganic layer UIO may be positioned on the mask substrate MSUB, and may be positioned to surround the exposed portion exp of the upper surface s1 of the mask substrate MSUB. The mask inorganic layer UIO may include a tip TIP more protruded toward (a center of) the cell area CA than the side s3 of the mask substrate MSUB.

The mask metal layer MML included in the mask MK11 may be positioned on the lower surface s2 of the mask substrate MSUB, and may be in contact with the lower surface s2 of the mask substrate MSUB. On the cross-section, the mask metal layer MML included in the mask MK11 may be positioned at a portion that overlaps the first cell peripheral area CRA1 and the edge area EDA. On the cross-section, the mask metal layer MML included in the mask MK11 may not overlap the second cell peripheral area CRA2.

The mask metal layer MML included in the mask MK11 may overlap the exposed portion exp of the upper surface s1 of the mask substrate MSUB in the third direction (Z-axis direction). The height Hm of the mask metal layer MML may be about 500 nanometers or greater.

The mask metal layer MML included in the mask MK11 may include a lower surface m2 facing the lower surface s2 of the mask substrate MSUB. The lower surface m2 of the mask metal layer MML may be a direction opposite to a direction in which the mask substrate MSUB is positioned.

In some embodiments, the mask metal layer MML included in the mask MK11 may include a heat-affected portion HAZ on the lower surface m2 of the mask metal layer MML, but is not limited thereto. According to the embodiment, the mask metal layer MML included in the mask MK11 may not include a heat-affected portion HAZ. Any repetitive detailed description of other features of the heat-affected portion HAZ will be omitted.

The mask MK11 may include a mask substrate MSUB and a mask inorganic layer UIO at a portion that overlaps the second cell peripheral area CRA2. The mask MK11 may not include the mask metal layer MML at a portion that overlaps the second cell peripheral area CRA2. Any repetitive detailed description of the same or like elements as those described above will be omitted.

In an embodiment, the mask MK11 may include a mask metal layer MML at a portion that overlaps the edge area EDA and the first cell peripheral area CRA1 of the mask substrate MSUB. The mask MK11 may planarize the warpage portion of the mask substrate MSUB by irradiating a laser to the mask metal layer MML, which overlaps the warpage portion of the mask substrate MSUB, and melting and condensing a portion of the mask metal layer MML in the manufacturing process. In such an embodiment, the laser may be radiated toward the lower surface m2 of the mask metal layer MML by the laser process included in the mask MK11. Therefore, the mask metal layer MML included in the mask MK11 may include a heat-affected portion HAZ on the lower surface m2, but is not limited thereto. Therefore, the mask MK11 may improve a tight adhesion to the display panel 410, thereby resolving the deposition defect of the display panel 410.

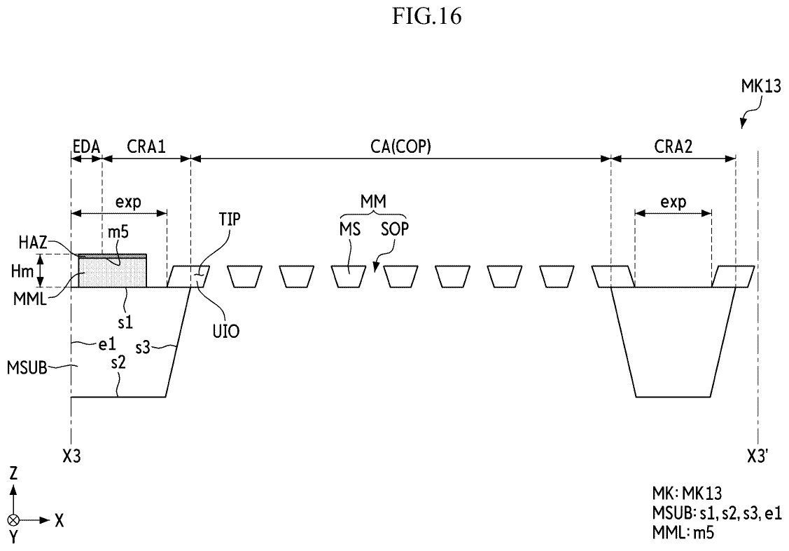

FIG. 16 is a cross-sectional view taken along line X3-X3′ in FIG. 14, according to another embodiment.

Referring to FIG. 16, the mask substrate MSUB, the mask inorganic layer UIO and the mask membrane MM, which are included in the mask MK13, may have the same structure and characteristics as those of the mask MK11 shown in FIGS. 14 and 15. Hereinafter, differences between the mask MK11 shown in FIGS. 14 and 15 and the mask MK13 shown in FIG. 16 will be described.

In an embodiment, the mask metal layer MML included in the mask MK13 may be positioned on the upper surface s1 of the mask substrate MSUB at a portion that overlaps the edge area EDA and the first cell peripheral area CRA1. The mask metal layer MML included in the mask MK13 may not overlap the second cell peripheral area CRA2. The mask metal layer MML included in the mask MK13 may be in contact with the exposed portion exp of the upper surface s1 of the mask substrate MSUB.

The mask metal layer MML included in the mask MK13 may be spaced apart from the mask inorganic layer UIO in the first direction (X-axis direction). In addition, the mask metal layer MML may be positioned on a same plane as the mask inorganic layer UIO and the mask membrane MM in the first direction (X-axis direction). In other words, the mask metal layer MML included in the mask MK13 may be positioned on a same plane as the mask shadow MS in the first direction (X-axis direction). The height Hm of the mask metal layer MML may be about 500 nanometers or greater. Any repetitive detailed description of the same or like elements as those described above will be omitted.

In some embodiments, the mask metal layer MML may include an upper surface m5 positioned in a direction opposite to a direction toward the mask substrate MSUB.

In some embodiments, the mask metal layer MML included in the mask MK13 may include a heat-affected portion HAZ on the upper surface m5 of the mask metal layer MML, but is not limited thereto. According to an embodiment, the mask metal layer MML included in the mask MK13 may not include a heat-affected portion HAZ. any repetitive detailed description of other features of the heat-affected portion HAZ will be omitted.

In an embodiment, the mask MK13 may include a mask substrate MSUB and a mask inorganic layer UIO at a portion that overlaps the second cell peripheral area CRA2. The mask MK13 may not include the mask metal layer MML at a portion that overlaps the second cell peripheral area CRA2. Any repetitive detailed description of the same or like elements as those described above will be omitted.

The mask MK13 may include a mask metal layer MML at a portion that overlaps the edge area EDA and the first cell peripheral area CRA1 of the mask substrate MSUB. The mask MK13 may planarize the warpage portion of the mask substrate MSUB by radiating a laser to the mask metal layer MML, which overlaps the warpage portion of the mask substrate MSUB, and melting and condensing a portion of the mask metal layer MML in the manufacturing process. In such an embodiment, the laser may be radiated toward the upper surface m5 of the mask metal layer MML by the laser process included in the mask MK13. Therefore, the mask metal layer MML included in the mask MK13 may include a heat-affected portion HAZ on the upper surface m5, but is not limited thereto. Therefore, the mask MK13 may improve a tight adhesion to the display panel 410, thereby resolving the deposition defect of the display panel 410.

The display device according to one embodiment of the present disclosure can be applied to various electronic devices. The electronic device according to the one embodiment of the present disclosure includes the display device described above, and may further include modules or devices having additional functions in addition to the display device.

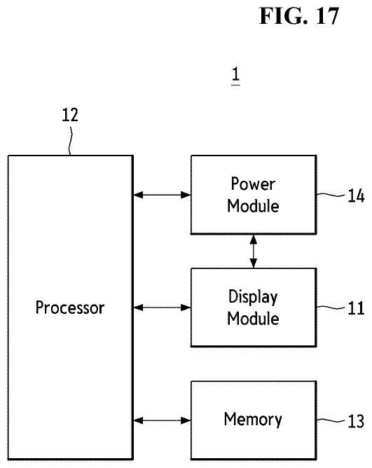

FIG. 17 is a block diagram of an electronic device according to one embodiment of the present disclosure.

Referring to FIG. 17, the electronic device 1 according to one embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for the operation of the processor 12 or the display module 11. When the processor 12 executes an application stored in the memory 15, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the one embodiment of the present disclosure may be included in the display device 10 according to the embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

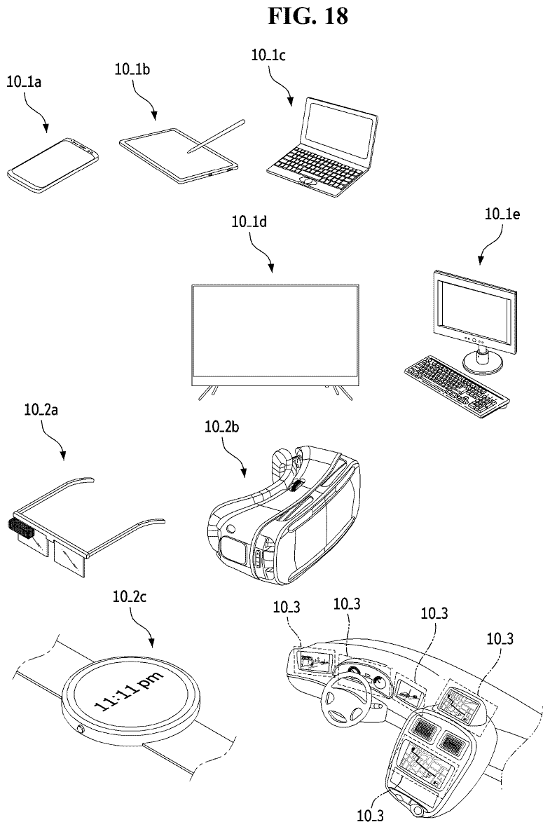

FIG. 18 is a schematic diagram of an electronic device according to various embodiments of the present disclosure.

Referring to FIG. 18, various electronic devices to which display devices 10 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

Although embodiments of the disclosure have been described with reference to the accompanying drawings, those skilled in the art would understand that various modifications and alterations may be made without departing from the technical idea or essential features of the disclosure. Therefore, it should be understood that the above-mentioned embodiments are not limiting but illustrative in all aspects.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A deposition mask comprising:
a mask substrate including a cell area and a cell peripheral area;
a mask membrane positioned in the cell area of the mask substrate, wherein a pixel opening is defined through the mask membrane, and the mask membrane includes a mask shadow surrounding the pixel opening; and
a mask frame positioned on the cell peripheral area of the mask substrate, wherein the mask frame includes the mask substrate, a mask inorganic layer and a mask metal layer,
wherein the mask metal layer does not overlap the cell area in a direction perpendicular to the mask substrate and is in contact with the mask substrate, and
the mask metal layer includes a portion condensed or melted by laser irradiation.

2. The deposition mask of claim 1, wherein the mask metal layer includes a first surface positioned in a direction opposite to a direction in which the mask substrate is positioned, and
the first surface includes a heat-affected portion defined by the portion condensed or melted by laser irradiation.

3. The deposition mask of claim 2, wherein the heat-affected portion has a smoked shape, a corrugated shape or an embossed shape.

4. The deposition mask of claim 3, wherein the first surface is entirely covered by the heat-affected portion.

5. The deposition mask of claim 3, wherein the heat-affected portion includes a protrusion more protruded in the direction perpendicular to the mask substrate than the first surface.

6. The deposition mask of claim 3, wherein the heat-affected portion includes a recess more recessed in the direction perpendicular to the mask substrate than the first surface.

7. The deposition mask of claim 1, wherein the mask substrate further includes an upper surface directed toward the mask inorganic layer and a lower surface opposite to the upper surface,
the mask inorganic layer is in contact with the upper surface of the mask substrate, and
the upper surface of the mask substrate includes an exposed portion which is not in contact with the mask inorganic layer.

8. The deposition mask of claim 7, wherein the mask metal layer overlaps the exposed portion of the upper surface in the direction perpendicular to the mask substrate.

9. The deposition mask of claim 8, wherein the mask metal layer is in contact with the lower surface of the mask substrate.

10. The deposition mask of claim 8, wherein the mask metal layer is in contact with the upper surface of the mask substrate.

11. The deposition mask of claim 10, wherein the mask metal layer is spaced apart from the mask inorganic layer in a direction parallel with the mask substrate, and
the mask metal layer is positioned on a same plane parallel with the mask substrate as the mask membrane.

12. The deposition mask of claim 1, wherein the mask metal layer has a height of about 500 nanometers or greater.

13. The deposition mask of claim 1, wherein the mask inorganic layer includes a tip more protruded toward a center of the cell area than a side of the mask substrate, and
the mask metal layer does not overlap the protruded tip of the mask inorganic layer in the direction perpendicular to the mask substrate.

14. The deposition mask of claim 1, wherein the mask substrate includes silicon, and
the mask substrate has a circular shape.

15. The deposition mask of claim 1, wherein the mask frame defines a mask opening on a plane, and
the mask metal layer surrounds the mask opening on the plane.

16. The deposition mask of claim 15, wherein the mask metal layer exposes the mask opening and is in a mesh shape on the plane.

17. The deposition mask of claim 1, wherein the mask inorganic layer includes an inorganic insulating material, and
the mask inorganic layer and the mask shadow include a same material as each other.

18. A deposition mask comprising:
a mask substrate including a cell area, an edge area and a cell peripheral area positioned between the cell area and the edge area;
a mask membrane positioned in the cell area of the mask substrate;
a mask inorganic layer positioned on the cell peripheral area of the mask substrate; and
a mask metal layer positioned on the cell peripheral area and the edge area of the mask substrate, wherein the mask metal layer includes a metal,
wherein the mask metal layer includes a heat-affected portion.

19. The deposition mask of claim 18, wherein the cell peripheral area includes a first cell peripheral area which overlaps the mask metal layer in a direction perpendicular to the mask substrate, and a second cell peripheral area which does not overlap the mask metal layer in the direction perpendicular to the mask substrate, and
the mask metal layer does not overlap the cell area in the direction perpendicular to the mask substrate.

20. The deposition mask of claim 19, wherein the mask metal layer includes a first surface positioned in a direction opposite to a direction in which the mask substrate is positioned, and
the first surface includes the heat-affected portion.

21. An electronic device comprising:
a display device including a display panel formed using a deposition mask;
the mask substrate including a cell area and a cell peripheral area;
a mask membrane positioned in the cell area of the mask substrate, wherein a pixel opening is defined through the mask membrane, and the mask membrane includes a mask shadow surrounding the pixel opening; and
a mask frame positioned on the cell peripheral area of the mask substrate, wherein the mask frame includes the mask substrate, a mask inorganic layer and a mask metal layer,
wherein the mask metal layer does not overlap the cell area in a direction perpendicular to the mask substrate and is in contact with the mask substrate, and
the mask metal layer includes a portion condensed or melted by laser irradiation.
